(19) United States
(12) Patent Application Publication
(10) Pub. No.: US 2026/0129747 A1
(43) Pub. Date: May 7, 2026

(54) PRINTED CIRCUIT BOARD

(71) Applicant: SAMSUNG ELECTRO-MECHANICS CO., LTD., Suwon-si (KR)

(72) Inventor: In Gun KIM, Suwon-si (KR)

(73) Assignee: SAMSUNG ELECTRO-MECHANICS CO., LTD., Suwon-si (KR)

(21) Appl. No.: 19/175,080

(22) Filed: Apr. 10, 2025

(30) Foreign Application Priority Data
Nov. 6, 2024 (KR) 10-2024-0155978

(51) Int. Cl. H05K 1/02; H05K 1/03; H05K 1/11

(52) U.S. Cl. CPC H05K 1/0271; H05K 1/0306; H05K 1/115; H05K 2201/0175

(57) ABSTRACT

A printed circuit board includes a frame having a through-portion, a core layer disposed within the through-portion, the core layer comprising a glass layer and a metal via that passes through at least a portion of the glass layer, and a first insulating layer that covers at least a portion of both the frame and the core layer, the insulating layer filling at least a portion of the through-portion. In one embodiment, the overall thickness of the frame is greater than the overall thickness of the core layer, thereby facilitating improved process capability and enhanced variation characteristics. The printed circuit board is particularly suited for high-performance and miniaturized electronic applications.

### CROSS-REFERENCE TO RELATED APPLICATION(S)

This application claims benefit of priority to Korean Patent Application No. 10-2024-0155978 filed on Nov. 6, 2024 in the Korean Intellectual Property Office, the disclosure of which is incorporated herein by reference in its entirety.

### TECHNICAL FIELD

The present disclosure relates to a printed circuit board.

In order to cope with high performance and miniaturization strategies of semiconductors, a level of miniaturization and densification required for printed circuit boards has been increasing. For example, in order to manufacture high-end products such as a server substrate, a high multilayer and a large body have been required. However, as the number of wiring layers increases and a size of a body increases, a substrate may be more vulnerable to warpage. In order to solve such an issue, using a glass core has been considered.

### SUMMARY

An aspect of the present disclosure is to improve process capability and variation characteristics of a printed circuit board including a glass layer, the printed circuit board having a fine via and a fine insulating thickness.

A core layer including a glass layer may be disposed in a through-portion formed in a frame, and the overall thickness of the frame may be made thicker than that of the core layer, such that the frame and an insulating layer, stacked on the core layer, maintain a constant thickness tolerance between them.

In this case, a central line of the frame in a thickness direction and a central line of the core layer in a thickness direction may be disposed on different levels. In addition, when an external surface of the frame is viewed through in a direction, perpendicular to the thickness direction, connection vias, formed on upper sides of the frame and the insulating layer, may at least partially overlap each other, and connection vias, formed on lower sides of the frame and the insulating layer, may not entirely overlap each other.

According to an aspect of the present disclosure, there is provided a printed circuit board including a frame having a through-portion, a core layer having at least a portion disposed in the through-portion, the core layer including a glass layer and a metal via passing through at least a portion of the glass layer, and a first insulating layer covering at least a portion of each of the frame and the core layer, the first insulating layer filling at least a portion of the through-portion. An overall thickness of the frame may be greater than an overall thickness of the core layer.

According to another aspect of the present disclosure, there is provided a printed circuit board including a frame having a through-portion, a core layer having at least a portion disposed in the through-portion, the core layer including a glass layer and a metal via passing through at least a portion of the glass layer, a first insulating layer covering at least a portion of each of the frame and the core layer, the first insulating layer filling at least a portion of the through-portion, a first connection via passing through at least a portion of an upper side of the first insulating layer, the first connection via connected to an upper side of the metal via, and a second connection via passing through at least a portion of a lower side of the first insulating layer, the second connection via connected to a lower side of the metal via. When an external surface of the frame is viewed through in a direction, perpendicular to a thickness direction, the frame and the first connection via may at least partially overlap each other.

According to example embodiments of the present disclosure, a printed circuit board including a glass layer, wherein the printed circuit board comprises a fine via and a fine insulating thickness, may have improved process capability and variation characteristics.

### BRIEF DESCRIPTION OF DRAWINGS

The foregoing and other aspects, features, and advantages of the present disclosure will be more clearly understood from the following detailed description, taken in conjunction with the accompanying drawings, in which:

FIG. 1 is a schematic block diagram of an example of an electronic device system;

FIG. 2 is a schematic cross-sectional view of an example of a printed circuit board;

FIG. 3 is a schematic cross-sectional view of another example of a printed circuit board;

FIG. 4 is a schematic cross-sectional view of yet another example of a printed circuit board; and

FIG. 5 is a schematic cross-sectional view of another example of a printed circuit board.

### DETAILED DESCRIPTION

Hereinafter, example embodiments of the present disclosure are described with reference to the accompanying drawings. The shapes and sizes of components in the drawings may be exaggerated or reduced for clearer description.

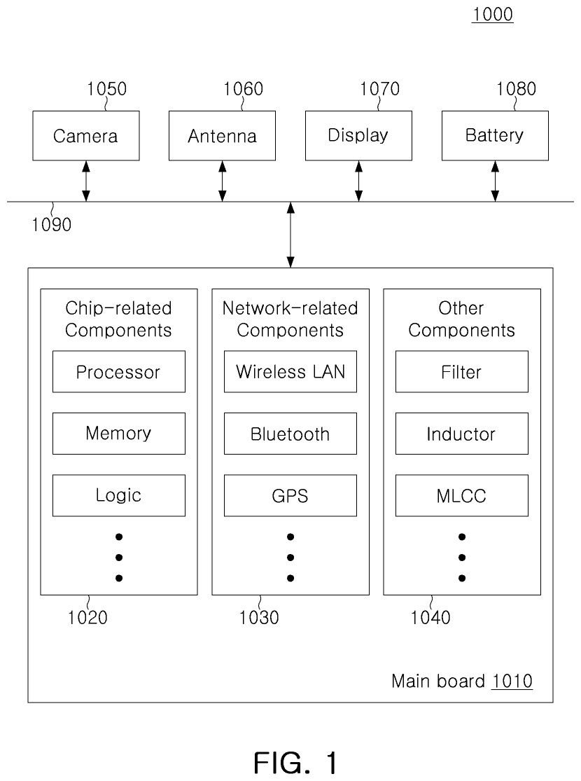

FIG. 1 is a schematic block diagram of an example of an electronic device system.

Referring to the drawings, an electronic device 1000 may accommodate a mainboard 1010. The mainboard 1010 may include chip-related components 1020, network-related components 1030, and other components 1040, physically or electrically connected thereto. Such components may be connected to other components to be described below to form various signal lines 1090.

The chip-related components 1020 may include a memory chip such as a volatile memory (for example, a dynamic random access memory (DRAM)), a non-volatile memory (for example, a read only memory (ROM)), or a flash memory, an application processor chip such as a central processor (for example, a central processing unit (CPU)), a graphics processor (for example, a graphics processing unit (GPU)), a digital signal processor, a cryptographic processor, a microprocessor, or a microcontroller, and a logic chip such as an analog-to-digital converter or an application-specific integrated circuit (ASIC). However, the chip-related components 1020 are not limited thereto, and may include other types of chip-related components. In addition, the chip-related components 1020 may be combined with each other. The chip-related components 1020 may be in the form of a package including the above-described chip or electronic component.

The network-related components 1030 may include protocols such as wireless fidelity (Wi-Fi) (Institute of Electrical And Electronics Engineers (IEEE) 802.11 family or the like), worldwide interoperability for microwave access (WiMAX) (IEEE 802.16 family or the like), IEEE 802.20, long term evolution (LTE), evolution data only (Ev-DO), high speed packet access+(HSPA+), high speed downlink packet access+(HSDPA+), high speed uplink packet access+(HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth®, 3G, 4G, and 5G protocols, and any other wireless and wired protocols, designated after the above-described protocols. However, the network-related components 1030 are not limited thereto, and may also include a variety of other wireless or wired standards or protocols. In addition, the network-related components 1030 may be combined with each other, together with the chip-related components 1020 described above.

The other components 1040 may include a high-frequency inductor, a ferrite inductor, a power inductor, ferrite beads, a low temperature co-fired ceramic (LTCC), an electromagnetic interference (EMI) filter, a multilayer ceramic capacitor (MLCC), or the like. However, the other components 1040 are not limited thereto, and may also include passive components used for various other purposes, or the like. In addition, the other components 1040 may be combined with each other, together with the chip-related components 1020 or the network-related components 1030 described above.

Depending on a type of the electronic device 1000, the electronic device 1000 may include other components that may be or may not be physically or electrically connected to the mainboard 1010. The other components may include, for example, a camera module 1050, an antenna module 1060, a display 1070, a battery 1080, and similar components. However, the other components are not limited to these examples and may include an audio codec, a video codec, a power amplifier, a compass, an accelerometer, a gyroscope, a speaker, a mass storage unit (e.g., a hard disk drive), a compact disc (CD), a digital versatile disc (DVD), or similar components. In addition, the other components may also include additional components used for various purposes depending on the type of electronic device 1000.

The electronic device 1000 may be a smartphone, a personal digital assistant (PDA), a digital video camera, a digital still camera, a network system, a computer, a monitor, a tablet PC, a laptop PC, a netbook PC, a television, a video game machine, a smartwatch, an automotive component, or the like. However, the electronic device 1000 is not limited thereto, and may be any other electronic device to process data.

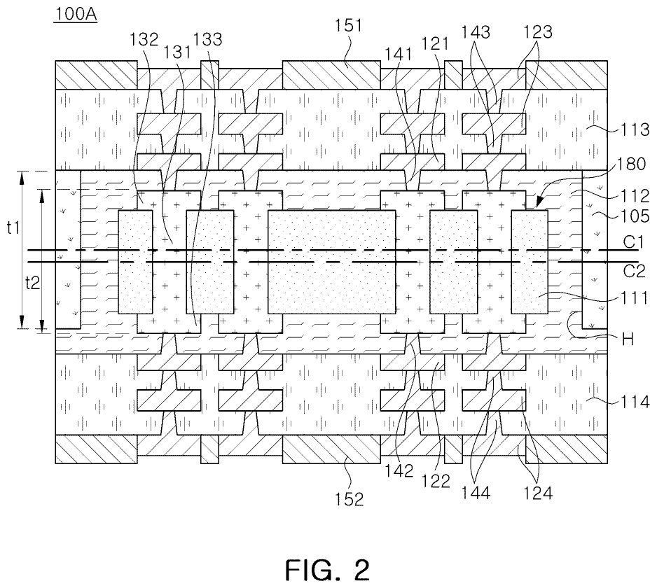

FIG. 2 is a schematic perspective view of an example electronic device.

Referring to the drawings, a printed circuit board 100A according to an example may include a frame 105 having a through-portion H, a core layer 180 having at least a portion disposed in the through-portion H, the core layer 180 including a glass layer 111, a metal via 131 passing through at least a portion of the glass layer 111, a first metal pad 132 disposed on an upper surface of the glass layer 111 and connected to the metal via 131, and a second metal pad 133 disposed on a lower surface of the glass layer 111 and connected to the metal via 131, a first insulating layer 112 covering at least a portion of each of the frame 105 and the core layer 180, the first insulating layer 112 filling at least a portion of the through-portion H, a first wiring layer 121 disposed on an upper surface of the first insulating layer 112, a second wiring layer 122 disposed on a lower surface of the first insulating layer 112, a first connection via 141 passing through at least a portion of an upper side of the first metal pad 132, the first connection via 141 connected to the first metal pad 132, and a second connection via 142 passing through at least a portion of a lower side of the first insulating layer 112, the second connection via 142 connected to the second metal pad 133.

As described, the printed circuit board 100A according to an example may include the frame 105 having the through-portion H, and the core layer 180 including the glass layer 111 may be disposed in the through-portion H. Accordingly, process warpage may be more easily controlled. In addition, the frame 105 may be provided at a panel level. In this case, a plurality of substrate units may be manufactured in a single process using the frame 105 as a jig, and a plurality of unit substrates may be obtained in a singulation process. In addition, the frame 105 and the core layer 180 may be surrounded and the through-portion H may be filled through the first insulating layer 112, thereby obtaining a stress relief effect. Furthermore, more diverse wiring may be designed through the first and second wiring layers 121 and 122, and an electrical connection path may be provided through the first and second connection vias 141 and 142. In addition, the first wiring layer 121 and the first connection via 141 may be formed as a fine wiring and a fine via, and thus may be easily used for rewiring a semiconductor chip mounted on a substrate. For example, a thickness of the first connection via 141 may be greater than 0 μm and less than or equal to 20 μm, and a diameter of an upper end of the first connection via 141 may be greater than 0 μm and less than or equal to 20 μm.

The frame 105 may be manufactured separately from the core layer 180, such that the frame 105 may have different thickness variations. A thickness variation refers to the overall thickness difference that includes any plating or metal layer formed on the frame 105 and the core layer 180. Accordingly, the frame 105 and the core layer 180 may exhibit significant thickness variation. In this case, there may be limitations in providing a fine insulating thickness necessary for forming a fine circuit and a fine via. Thus, in the printed circuit board 100A according to one example, the overall thickness t1 of the frame 105 may be greater than the overall thickness t2 of the core layer 180. Moreover, the central line C1 of the frame 105 in the thickness direction and the central line C2 of the core layer 180 may be disposed at different levels, thereby maintaining a fine thickness at the upper portion of the first insulating layer 112 that includes the first connection via 141. Consequently, when a fine via and a fine insulating thickness are formed, process capability and variation characteristics may be improved. The overall thickness t1 of the frame 105 refers to the thickness of the frame body as well as any plating or metal layer formed on the frame 105. Similarly, the overall thickness t2 of the core layer 180 takes into account not only the thickness of the glass layer 111 but also the thicknesses of the first and second metal pads 132 and 133. For example, the overall thickness of the core layer 180 may be the sum of the thickness of the glass layer 111 and the thicknesses of the first and second metal pads 132 and 133.

In such a point of view, an upper surface of the frame 105 may be substantially coplanar with an upper surface of the first insulating layer 112. Accordingly, when an external surface of the frame 105 is viewed through in a direction, perpendicular to the thickness direction, the frame 105 and the first connection via 141 may at least partially overlap each other. In addition, a lower surface of the frame 105 may be disposed above a lower surface of the core layer 180. Accordingly, when the external surface of the frame 105 is viewed through in a direction, perpendicular to the thickness direction, the frame 105 and the second connection via 142 may not entirely overlap each other. In this case, a fine thickness of an upper portion of the first insulating layer 112 having the first connection via 141 may be more easily and uniformly maintained. Accordingly, when a fine via and a fine insulating thickness are formed, process capability and variation characteristics may be further improved. The upper surface or the lower surface of the frame 105 may refer to an uppermost surface or a lowermost surface considering not only a body of the frame 105 but also a plating layer or a metal layer that may be formed on the frame 105. In addition, an upper surface or a lower surface of the core layer 180 may refer to an uppermost surface or lowermost surface considering not only the glass layer 111 but also the first and second metal pads 132 and 133. For example, the upper surface and the lower surface of the core layer 180 may be an upper surface and a lower surface of each of the first and second metal pads 132 and 133.

The printed circuit board 100A according to an example may further include a second insulating layer 113 disposed on an upper surface of the first insulating layer 112, one or more third wiring layers 123 respectively disposed on or in the second insulating layer 113, one or more third via layers 143 respectively disposed in the second insulating layer 113, the one or more third via layers 143 connected to the one or more third wiring layers 123, a third insulating layer 114 disposed on a lower surface of the first insulating layer 112, one or more third wiring layers 123 respectively disposed on or in the second insulating layer 113; one or more third via layers 143 respectively disposed in the second insulating layer 113 and connected to the third wiring layers 123; a third insulating layer 114 disposed on the lower surface of the first insulating layer 112; one or more fourth wiring layers 124 respectively disposed on or in the third insulating layer 114; one or more fourth via layers 144 respectively disposed in the third insulating layer 114 and connected to the fourth wiring layers 124; a first resist layer 151 disposed on the upper surface of the second insulating layer 113; and a second resist layer 152 disposed on the lower surface of the third insulating layer 114, as necessary.

As described, the printed circuit board 100A according to an example may have a multilayer substrate structure in which a build-up layer is further formed on an upper side and a lower side of the core layer 180. For example, the printed circuit board 100A according to an example may be a package substrate on which a semiconductor chip is mounted. The package substrate may be a large-area substrate used for a server or the like. In this case, the semiconductor chip may be mounted on an upper side of the printed circuit board 100A, and the first wiring layer 121, the one or more third wiring layers 123, a first via layer including the first connection via 141, and the one or more third via layers 143 may be formed of a fine wiring and/or a fine circuit.

As necessary, the number of build-up layers formed on an upper side of the printed circuit board 100A may be greater than the number of build-up layers formed on a lower side of the printed circuit board 100A, or a build-up layer may be formed only at the upper side. For example, the printed circuit board 100A according to an example may have an asymmetric structure. For example, the printed circuit board 100A according to an example may be an interposer substrate. Even in this case, the semiconductor chip may be mounted on the upper side, and the first wiring layer 121, the one or more third wiring layers 123, a first via layer including the first connection via 141, and the one or more third via layers 143 may be formed of a fine wiring and/or a fine circuit.

An upper surface, an upper side, a lower surface, or a lower side, used to describe a structure of the printed circuit board 100A according to an example, is determined based on the accompanying drawings, but defines a direction for ease of description. “Upper” and “lower” may be opposite to each other depending on a product to which the printed circuit board 100A is applied.

Hereinafter, components of the printed circuit board 100A according to an example will be described in more detail with reference to the drawings.

The frame 105 may include a material having excellent rigidity, and may include, for example, a copper clad laminate (CCL) or an unclad CCL, but the present disclosure is not limited thereto. Alternatively, frame 105 may comprise other organic materials or other types of inorganic materials with excellent rigidity. The frame 105 may be used as a jig in a process, thereby enabling the process to be performed at a panel level. Additionally, the frame 105 may remain in the final unit after singulation, which can be advantageous for warpage control.

The glass layer 111 may include glass that is an amorphous solid. Glass may include, for example, pure silicon dioxide (about 100% SiO₂), soda lime glass, borosilicate glass, alumino-silicate glass, or the like, but the present disclosure is not limited thereto. An alternative glass material, such as fluorine glass, phosphate glass, chalcogen glass, or the like, may also be used as a material of the glass layer. In addition, other additives may be further included to form glass having specific physical properties. The above-described additives may include calcium carbonate (for example, lime) and sodium carbonate (for example, soda), as well as magnesium, calcium, manganese, aluminum, lead, boron, iron, chromium, potassium, sulfur, and antimony, and carbonates and/or oxides of the above-described elements and other elements. The glass layer 111 may be distinguished from an organic insulating material including a glass fiber (glass cloth and/or glass fabric), for example, a CCL, a prepreg (PPG), or the like. The glass layer 111 may be, for example, in the form of a glass plate.

Each of the first to third insulating layers 112, 113, and 114 may include an organic insulating material. The organic insulating material may comprise a thermosetting resin, such as an epoxy resin; a thermoplastic resin, such as polyimide; or an inorganic filler, an organic filler, and/or a glass fiber (e.g., glass cloth and/or glass fabric) combined with the resin. For example, the organic insulating material may be a PPG, an Ajinomoto build-up film (ABF), a photo imageable dielectric (PID), a bonding sheet (BS), or similar, although the present disclosure is not limited thereto. Each of the first through third insulating layers 112, 113, and 114 may comprise a plurality of layers. In this case, the plurality of layers may be integrated without boundaries therebetween, or may have distinct boundaries. In addition, the plurality of layers may comprise substantially the same insulating material, or may include different insulating materials.

Each of the first to fourth wiring layers 121, 122, 123, and 124 may include a metal. The metal may include copper (Cu), aluminum (Al), silver (Ag), tin (Sn), gold (Au), nickel (Ni), lead (Pb), titanium (Ti), and/or alloys thereof. For example, each of the first to third wiring layers 121, 122, and 123 may include a chemical copper, formed using electroless plating, as a seed layer, and may include an electrolytic copper, formed using electrolytic plating based on the same, as a pattern plating layer. Each of the first to fourth wiring layers 121, 122, 123 and 124 may perform various functions according to a design thereof. For example, a signal pattern, a power pattern, a ground pattern, or the like may be included. The patterns may be respectively in various forms, such as a line, a trace, a plane, a pad, and the like. The pad may be based on a concept including a land. Each of the third and fourth wiring layers 123 and 124 may include a plurality of layers. The third and fourth wiring layers 123 and 124 may have the same number of layers, but the present disclosure is not limited thereto, and may have different numbers of layers. For example, the number of layers of the third wiring layer 123 may be greater than the number of layers of the fourth wiring layer 124.

The metal via 131 may include a metal. The metal may include copper (Cu), aluminum (Al), silver (Ag), tin (Sn), gold (Au), nickel (Ni), lead (Pb), titanium (Ti), and/or alloys thereof. For example, the metal via 131 may include a multilayer structure of a titanium layer and a copper layer, formed using sputtering and/or electroless plating, as a seed layer. For example, the metal via 131 may include a sputtered titanium and a chemical copper, or a sputtered titanium, a sputtered copper, and a chemical copper. In addition, the metal via 131 may include a copper layer, formed using electrolytic plating based on the same, as a plating layer. For example, the metal via 131 may include an electrolytic copper. The metal via 131 may include various types of metal vias according to a design thereof. For example, a metal via for signal transmission, a metal via for power transmission, a metal via for ground transmission, or the like may be included. The metal via 131 may include various types of metal vias according to its design; for example, it may serve as a metal via for signal transmission, power transmission, or ground transmission. The metal via 131 may have a cylindrical shape with a substantially vertical side surface, although the present disclosure is not limited thereto and may also include a tapered side surface, such as an hourglass shape. The metal via 131 may have either a fill plating structure or a conformal plating structure; in some cases, a filler may be included therein. Furthermore, the metal via 131 may be provided as a plurality of metal vias 131, which may be arranged spaced apart from each other.

Each of the first and second metal pads 132 and 133 may include a metal. The metal may include copper (Cu), aluminum (Al), silver (Ag), tin (Sn), gold (Au), nickel (Ni), lead (Pb), titanium (Ti), and/or alloys thereof. For example, each of the first and second metal pads 132 and 133 may include a multilayer structure of a titanium layer and a copper layer, formed using sputtering and/or electroless plating, as a seed layer. For example, each of the first and second metal pads 132 and 133 may include a sputtered titanium and a sputtered copper, a sputtered titanium and a chemical copper, or a sputtered titanium, a sputtered copper, and a chemical copper, as a plating layer. In addition, each of the first and second metal pads 132 and 133 may include a copper layer, formed using electrolytic plating based on the same, as a plating layer. For example, each of the first and second metal pads 132 and 133 may include an electrolytic copper. Each of the first and second metal pads 132 and 133 may include various types of metal vias according to a design thereof. For example, a metal pad for signal transmission, a metal pad for power transmission, a metal pad for ground transmission, or the like may be included. Each of the first and second metal pads 132 and 133 may have a circular or elliptical shape on a plane, but the present disclosure is not limited thereto, and may have a polygonal shape, as necessary. When the metal via 131 is provided as a plurality of metal vias 131, the first and second pads 132 and 133 may be provided as a plurality of first and second metal pads 132 and 133 to correspond thereto.

The first and second connection vias 141 and 142 may be connection vias respectively included in the first and second via layers. Each of the first and second via layers and the third and fourth via layers 143 and 144 may include a metal. The metal may include copper (Cu), aluminum (Al), silver (Ag), tin (Sn), gold (Au), nickel (Ni), lead (Pb), titanium (Ti), and/or alloys thereof. For example, each of the first and second via layers and the third and fourth via layers 143 and 144 may include a chemical copper, formed using electroless plating, as a seed layer, and may include an electrolytic copper, formed using electrolytic plating based on the same, as a pattern plating layer. The first and second via layers and the third and fourth via layers 143 and 144 may perform various functions according to a design thereof. For example, a connection via for signal transmission, a connection via for power transmission, a connection via for ground transmission, or the like may be included. Each of the first and second via layers 143 and 144 may include a filled via in which a via hole is filled with a metal, but may include a conformal via in which a metal is disposed along a wall surface of a via hole. A connection via, included in each of the first and second via layers and the third and fourth via layers 143 and 144, may have a tapered shape. Each of the first and second via layers and the third and fourth via layers 143 and 144 may include a plurality of connection vias. Each of the third and fourth via layers 143 and 144 may include a plurality of layers. Although the third and fourth via layers may have the same number of layers, the present disclosure is not limited thereto, and they may have a different number of layers. For example, the number of layers in the third via layer 143 may be greater than that in the fourth via layer 144.

Each of the first and second resist layers 151 and 152 may comprise an organic insulating material. The organic insulating material may include a thermosetting resin such as an epoxy resin, a thermoplastic resin such as polyimide, or an inorganic filler and/or an organic filler, together with the resin. For example, the organic insulating material may be an ABF, a PID, a solder resist (SR), or the like, but the present disclosure is not limited thereto. Each of the first and second resist layers 151 and 152 may include a plurality of layers. The first resist layer 151 may have an opening, exposing at least a portion of an uppermost third wiring layer 123. The second resist layer 152 may have an opening, exposing at least a portion of a lowermost fourth wiring layer 124. Each opening may be a plurality of openings. A portion, exposed through an opening, may be a solder mask defined (SMD) and/or a non-solder mask defined (NSMD)-type portion.

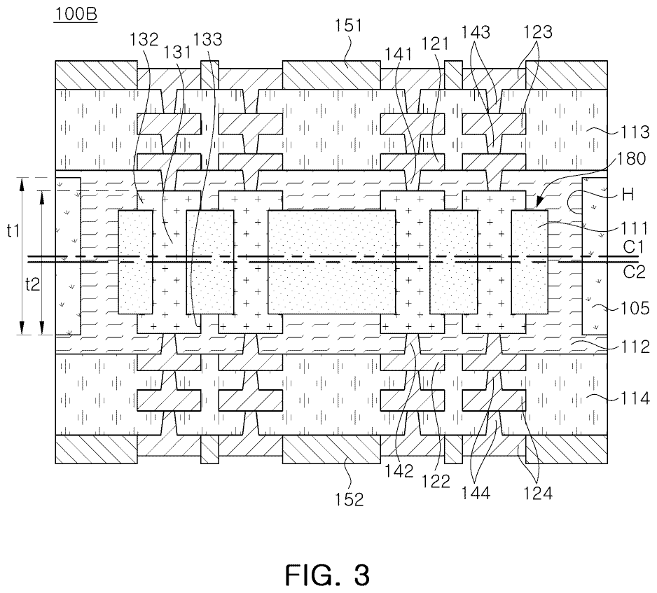

FIG. 3 is a schematic cross-sectional view of another example of a printed circuit board.

Referring to the drawings, an arrangement of a frame of the printed circuit board 100B according to another example may be partially different from that of the above-described printed circuit board 100A according to an example. For example, a lower surface of the frame 105 may be substantially coplanar with the lower surface of a core layer 180, and an upper surface of the frame 105 may be disposed above an upper surface of the core layer 180. Even in this case, the above-described technical effects may be included in substantially the same manner. For example, in the printed circuit board 100B according to another example, an overall thickness t1 of the frame 105 may be greater than an overall thickness t2 of the core layer 180, and a central line C1 of the frame 105 in a thickness direction and a center line C2 of the core layer 180 in the thickness direction may be disposed on different levels. Additionally, when the external surface of the frame 105 is viewed in a direction perpendicular to the thickness direction, the frame 105 and the first connection via 141 may at least partially overlap, whereas the frame 105 and the second connection via 142 may not entirely overlap. Consequently, a fine thickness of the upper portion of the first insulating layer 112, which includes the first connection via 141, may be maintained. Thus, when a fine via and a fine insulating thickness are formed, process capability and variation characteristics may be improved.

Other descriptions may be substantially the same as those of the above-described printed circuit board 100A according to an example.

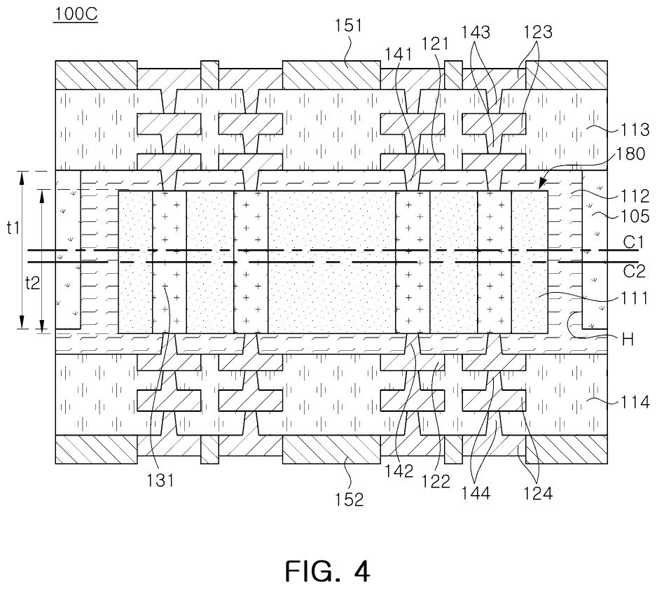

FIG. 4 is a schematic cross-sectional view of another example of a printed circuit board.

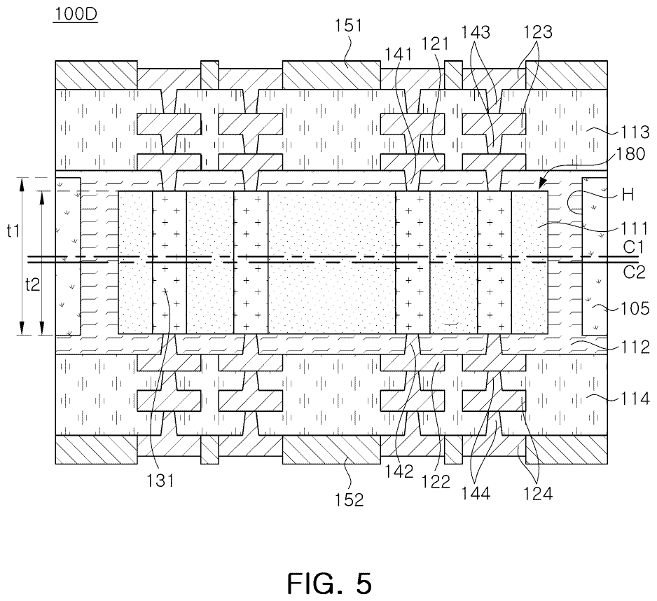

FIG. 5 is a schematic cross-sectional view of another example of a printed circuit board.

Referring to the drawings, unlike the above-described printed circuit board 100A according to an example and the above-described printed circuit board 100B according to another example, in each of printed circuit boards 100C and 100D according to another example, first and second metal pads 132 and 133 may be omitted from a core layer 180. For example, each of first and second connection vias 141 and 142 may be directly connected to a metal via 131. In this case, a direct wiring may be omitted from a glass layer 111, thereby reducing process difficulty and improving reliability. Even in this case, the above-described technical effects may be included in substantially the same manner. For example, in the printed circuit boards 100C and 100D according to another example, an overall thickness t1 of the frame 105 may be greater than an overall thickness t2 of the core layer 180, and a central line C1 of the frame 105 in a thickness direction and a center line C2 of the core layer 180 in the thickness direction may be disposed on different levels. In addition, when an external surface of the frame 105 is viewed through in a direction, perpendicular to the thickness direction, the frame 105 and a first connection via 141 may at least partially overlap each other, and the frame 105 and a second connection via 142 may not entirely overlap each other. Accordingly, a fine thickness of an upper portion of a first insulating layer 112 having the first connection via 141 may be maintained. Accordingly, when a fine via and a fine insulating thickness are formed, process capability and variation characteristics may be improved.

Other descriptions may be substantially the same as those of the above-described printed circuit board 500A according to an example and the above-described printed circuit board 100B according to another example.

As used herein, the terms “cover,” “to cover,” and “covering” may include entirely covering as well as at least partially covering, and may include directly covering as well as indirectly covering. In addition, the terms “fill,” to fill,” and “filling” may include not only entirely filling, but also approximately filling, for example, may include a case in which some voids, pores or the like are present. In addition, the terms “surround,” “to surround,” and “surrounding” may include not only entirely surrounding but also approximately surrounding. In addition, exposing may include not only entirely exposing but also exposing at least a portion of a structure, and exposure may mean exposing a component from another component in which the component is buried. For example, an opening, exposing a pad, may be exposing the pad from a resist layer, and a surface treatment layer may be further disposed on the exposed pad.

As used herein, being disposed in a through-portion or a through-hole may include not only a case in which an object is completely disposed in the through-portion or the through-hole, but also a case in which a portion of an object protrudes upwardly or downwardly in cross-section. For example, in plan view, a case in which an object is disposed in the through-portion or the through-hole may be determined in a broader sense.

As used herein, a process error or a positional deviation occurring in a manufacturing process, an error in measurement, and the like may be included. For example, “substantially coplanar” may include not only “completely coplanar,” but also “approximately coplanar. ” In addition, “being disposed on substantially the same level” may include not only “being disposed on completely the same level,” but also “being disposed on approximately the same level. ” In addition, “having a substantially specific shape” may include not only “having a completely specific shape,” but also “having an approximately specific shape.”

As used herein, the same insulating material may mean not only the exact same insulating material, but also the same type of insulating material. Thus, compositions of insulating materials may be substantially the same, but specific composition ratios thereof may slightly vary.

As used herein, “in cross-section” may refer to the cross-sectional shape of an object when the object is vertically cut, or to the cross-sectional shape when the object is viewed in a side view. Additionally, “a shape on a plane” may refer to the shape of an object when it is horizontally cut, or to its planar shape when viewed from the top or bottom.

As used herein, an upper side, an upper portion, the upper surface, or the like is used to refer to a direction toward a surface on which an electronic component is mountable based on a cross-section of a drawing for ease, and a lower side, a lower portion, a lower surface, or the like is used to refer to an opposite direction thereof. However, the above-described directions are defined for ease of description. Thus, it should be understood that the scope of the claims is not particularly limited by the above-described directions, and the concepts of “upper”and “lower”may change at any time.

As used herein, the term “connected” may refer not only to “directly connected” but also to “indirectly connected” (for example, by means of an adhesive layer). The term “electrically connected” may encompass both cases where components are physically connected and where they are not. Additionally, the terms “first,” “second,” etc., are used merely to distinguish one component from another and do not imply any specific sequence, importance, or hierarchy. In some instances, a component designated as the first may be labeled as the second, and vice versa, without departing from the scope of the example embodiments.

As used herein, each of a thickness, a width, a length, a depth, a line width, a space, a pitch, a separation distance, a surface roughness, and the like may be measured using a scanning microscope or an optical microscope based on a cross-section obtained by polishing or cutting a printed circuit board. The cross-section may be a vertical cross-section or a horizontal cross-section, and each value may be measured based on the required cross-section. For example, a width of an upper end and/or lower end of a via may be measured in cross-section taken along a central axis of the via. When the value is not constant, the value may be determined as an average value of values measured at five arbitrary points. In this case, when a component does not have a predetermined value, the value may be determined as an average value of values measured at arbitrary five points.

As used herein, the term “an example” does not mean the same example embodiment, and is provided to emphasize different unique features. However, the examples presented above do not preclude implementation in combination with features of other examples. For example, a context described in a specific example may be used in other examples, even if it is not described in the other example examples, unless it is described contrary to or inconsistent with the context in the other examples.

The terms used herein describe particular examples only, and the present disclosure is not limited thereby. As used herein, singular forms “a,” “an,” and “the” are intended to include the plural forms as well, unless the context clearly indicates otherwise.

While example embodiments have been shown and described above, it will be apparent to those skilled in the art that modifications and variations can be made without departing from the scope of the present disclosure as defined by the appended claims.

1. A printed circuit board, comprising:
a glass layer having a through-hole;
a first insulating material disposed on a wall surface of the through-hole and in contact with the wall surface of the through-hole; and
a first metal via including a first metal seed layer disposed on the first insulating material, and a first metal layer disposed on the first metal seed layer and filling at least a portion of the through-hole.

2. The printed circuit board according to claim 1, wherein the first insulating material includes an organic insulating material.

3. (canceled)

4. The printed circuit board according to claim 21, wherein the second copper layer has a greater thickness than a thickness of at least one of the titanium layer or the first copper layer.

5. The printed circuit board according to claim 1, further comprising:
a first metal pattern connected to an upper side of the first metal via; and
a second metal pattern connected to a lower side of the first metal via,
wherein the first metal pattern includes the first metal seed layer extending onto an upper surface of the first insulating material and an upper surface of the glass layer, and the first metal layer extending onto the first metal seed layer from the upper surface of the first insulating material and the upper surface of the glass layer and protruding to an upper side of the first via hole, and
the second metal pattern includes the first metal seed layer extending onto a lower surface of the first insulating material and a lower surface of the glass layer, and the first metal layer extending onto the first metal seed layer from the lower surface of the first insulating material and the lower surface of the glass layer and protruding to a lower side of the first via hole.

6. The printed circuit board according to claim 5, wherein an extending portion of the first metal seed layer is in direct contact with the upper surface and the lower surface of the first insulating material, and the upper surface and the lower surface of the glass layer, respectively.

7. The printed circuit board according to claim 5, wherein the upper surface of the first insulating material is substantially coplanar with the upper surface of the glass layer, and
the lower surface of the first insulating material is substantially coplanar with the lower surface of the glass layer.

8. The printed circuit board according to claim 5, wherein the upper surface of the first insulating material is recessed downwardly from the upper surface of the glass layer,
the lower surface of the first insulating material is recessed upwardly from the lower surface of the glass layer,
the first metal pattern has a step structure on the upper surface of the first insulating material, and
the second metal pattern has a step structure on the lower surface of the first insulating material.

9. The printed circuit board according to claim 1, wherein the first insulating material has a first via hole in which the first metal via is disposed,
in a cross-section penetrating through the through-hole and the first via hole,
a shape of the through-hole and a shape of the first via hole are formed independently.

10. The printed circuit board according to claim 1, wherein the glass layer further has a through-portion spaced apart from the through-hole,
a second insulating material having a plurality of second via holes is disposed within the through-portion, and
a plurality of second metal vias are disposed within the plurality of second via holes, respectively,
wherein each of the plurality of second metal vias includes a second metal seed layer disposed on a wall surface of each of the plurality of second via holes, and a second metal layer disposed on the second metal seed layer and filling at least a portion of each of the plurality of second via holes.

11. (canceled)

12. The printed circuit board according to claim 10, wherein the plurality of second metal vias are connected to a plurality of third metal patterns on an upper side, respectively, and
the plurality of second metal vias are connected to a plurality of fourth metal patterns on a lower side, respectively,
wherein each of the plurality of third metal patterns includes the second metal seed layer extending onto an upper surface of the second insulating material, and the second metal layer extending onto the second metal seed layer from the upper surface of the second insulating material and protruding to an upper side of each of the plurality of second via holes, and
each of the plurality of fourth metal patterns includes the second metal seed layer extending onto a lower surface of the second insulating material, and the second metal layer extending onto the second metal seed layer from the lower surface of the second insulating material and protruding to a lower side of each of the plurality of second via holes.

13. The printed circuit board according to claim 10, wherein each of the upper surface and the lower surface of the second insulating material has a concave portion, and
at least one of the plurality of second via holes penetrates between a concave upper surface and a concave lower surface of the second insulating material.

14. The printed circuit board according to claim 13, further comprising:
a plurality of third metal patterns respectively connected to an upper side of each of the plurality of second metal vias;
a plurality of fourth metal patterns respectively connected to a lower side of each of the plurality of second metal vias;
a first metal pattern connected to an upper side of the first metal via; and
a second metal pattern connected to a lower side of the first metal via,
wherein an upper surface of at least one of the plurality of third metal patterns is disposed below an upper surface of the first metal pattern, and
a lower surface of at least one of the plurality of fourth metal patterns is disposed above a lower surface of the second metal pattern.

15. (canceled)

16. The printed circuit board of claim 1, further comprising:
a build-up portion including an insulating body disposed on the glass layer, one or more interconnection layers respectively disposed on or within the insulating body, and one or more via layers respectively disposed within the insulating body; and a semiconductor chip mounted on the build-up portion.

17. (canceled)

18. A printed circuit board, comprising:
a glass layer having a through-hole;
a first insulating material disposed within the through-hole and having a first via hole; and
a first metal via disposed within the first via hole,
wherein the first metal via includes:
a first metal layer in which at least a portion thereof is disposed on a wall surface of the first via hole;
a second metal layer in which at least a portion thereof is disposed on the first metal layer; and
a third metal layer disposed on the second metal layer and filling at least a portion of the first via hole,
wherein a nano void is formed at a boundary between the second metal layer and the first metal layer.

19. The printed circuit board according to claim 18,
wherein the first metal layer includes a sputtered copper layer and the second metal layer includes chemical copper.

20. The printed circuit board according to claim 18,
wherein the nano void is observable using a scanning electron microscope (SEM), a transmission electron microscope (TEM), a scanning transmission electron microscope (STEM), or a focused ion beam (FIB).

21. The printed circuit board according to claim 2, wherein the first metal seed layer includes a titanium layer disposed on the first insulating material, a first copper layer disposed on the titanium layer, and a second copper layer disposed on the first copper layer, and
the first metal layer is disposed on the second copper layer and includes a third copper layer filling at least a portion of the through-hole.

22. The printed circuit board according to claim 21, wherein the titanium layer is a sputtering layer including titanium,
the first copper layer is a sputtering layer including copper,
the second copper layer is an electroless copper plating layer, and
the third copper layer is an electrolytic copper plating layer.

23. The printed circuit board according to claim 21, wherein at least a portion of the second copper layer is in contact with the first insulating material in a center of the through-hole.

24. The printed circuit board according to claim 2, wherein the first metal seed layer includes a second copper layer disposed on the first insulating material, and
the first metal layer is disposed on the second copper layer and includes a third copper layer filling at least a portion of the through-hole.

25. The printed circuit board according to claim 24, wherein the second copper layer is an electroless copper plating layer, and
the third copper layer is an electrolytic copper plating layer.

26. The printed circuit board according to claim 2, wherein the first metal seed layer includes a titanium layer disposed on the first insulating material and a first copper layer disposed on the titanium layer, and
the first metal layer is disposed on the first copper layer and includes a third copper layer filling at least a portion of the through-hole.

27. The printed circuit board according to claim 26, wherein the titanium layer is a sputtering layer including titanium,
the first copper layer is a sputtering layer including copper,
the third copper layer is an electrolytic copper plating layer.
